(19) United States
(12) Patent Application Publication
(10) Pub. No.: US 2026/0262211 A1
(43) Pub. Date: Sep. 3, 2026

(54) BIT LINE/WORD LINE CONTACT STRING PROFILE IN SEMICONDUCTOR

(71) Applicant: NANYA TECHNOLOGY CORPORATION, New Taipei City (TW)

(72) Inventor: Shih-Ting HUANG, New Taipei City (TW)

(21) Appl. No.: 19/068,000

(22) Filed: Mar. 3, 2025

(51) Int. Cl. H10B 12/00

(52) U.S. Cl. CPC H10B 12/0335; H10B 12/485

(57) ABSTRACT

A method for forming a semiconductor structure comprises: forming a photoresist layer over a hard mask structure; patterning the photoresist layer, wherein the patterned photoresist layer has a rough surface; conformally depositing a spacer over the patterned photoresist layer, wherein during depositing the spacer, the rough surface of the patterned photoresist layer is repaired; and performing an etching process to the hard mask structure by using the patterned photoresist layer and the spacer as an etch mask.

### BACKGROUND

In the semiconductor industry, during the process of forming bit line/word line contact, undercut caused by exposing positive photoresist leads to uneven hole sizes in the exposed positive photoresist layer. This unevenness affects the subsequent ALD oxide deposition and etching processes, causing the hole sizes to remain uneven when transferring the pattern to the underlying layer, which in turn impacts the overall threshold voltage and IDS performance.

### SUMMARY

One aspect of the present disclosure provides a method for forming a semiconductor structure, comprising forming a photoresist layer over a hard mask structure; patterning the photoresist layer, wherein the patterned photoresist layer has a rough surface; conformally depositing a spacer over the patterned photoresist layer, wherein during depositing the spacer, the rough surface of the patterned photoresist layer is repaired; and performing an etching process to the hard mask structure by using the patterned photoresist layer and the spacer as an etch mask.

In some embodiments, the spacer is deposited using a plasma enhanced atomic layer deposition (PEALD) process, and wherein an RF power of the PEALD process is in a range from about 200 W to about 1000 W.

In some embodiments, a flow rate of a carrier gas of the PEALD process is in a range from about 1 slm to about 4 slm.

In some embodiments, the RF power is turned on for about 0.1 seconds to about 1 second in each deposition cycle of the PEALD process.

In some embodiments, a temperature for depositing the spacer is in a range from about 25° C. to about 300° C.

In some embodiments, the spacer is made of silicon oxide and is deposited using the PEALD process, and depositing the spacer comprises supplying a silicon source and an oxygen source, and wherein oxygen radicals are generated from the oxygen source during the PEALD process, and the rough surface of the patterned photoresist layer is repaired through the oxygen radicals.

In some embodiments, the hard mask structure comprises: a first hard mask; a first dielectric layer over the first hard mask; a second dielectric layer over the first dielectric layer; an underlayer over the second dielectric layer; and a second hard mask over the underlayer.

In some embodiments, the first hard mask is made of amorphous carbon, the first dielectric layer is made of silicon oxynitride, the second dielectric layer is made of silicon oxide, the underlayer is made of amorphous carbon, and the second hard mask is made of silicon oxide.

In some embodiments, the etching process is performed such that a pattern of the spacer and the patterned photoresist layer is transferred to the first dielectric layer and the second dielectric layer, and wherein the spacer, the patterned photoresist layer, the second hard mask, and the underlayer are completely removed once the etching process is complete.

In some embodiments, etchants of the etching process comprise C₄F₆ and C₄F₈.

In some embodiments, flow rates of the etchants are in a range from about 5 sccm to about 200 sccm, respectively.

One aspect of the present disclosure provides a method for forming a semiconductor structure, comprising: forming a photoresist layer over a hard mask structure, wherein the hard mask structure comprises: a first hard mask; a first dielectric layer over the first hard mask; a second dielectric layer over the first dielectric layer; an underlayer over the second dielectric layer; and a second hard mask over the underlayer. The method further comprising: patterning the photoresist layer; conformally depositing a spacer over a patterned photoresist layer; and performing an etching process to transfer the pattern of the spacer and the patterned photoresist layer to the first dielectric layer and the second dielectric layer, and wherein the spacer, the patterned photoresist layer, the second hard mask, and the underlayer are completely removed once the etching process is complete.

In some embodiments, the first hard mask is made of amorphous carbon, the first dielectric layer is made of silicon oxynitride, the second dielectric layer is made of silicon oxide, the underlayer is made of amorphous carbon, and the second hard mask is made of silicon oxide.

In some embodiments, etchants of the etching process comprise C₄F₆ and C₄F₈.

In some embodiments, flow rates of the etchants are in a range from about 5 sccm to about 200 sccm, respectively.

In some embodiments, the etching process is performed for about 5 seconds to about 200 seconds.

In some embodiments, the spacer is deposited using a plasma enhanced atomic layer deposition (PEALD) process, and wherein an RF power of the PEALD process is in a range from about 200 W to about 1000 W.

In some embodiments, a flow rate of a carrier gas of the PEALD process is in a range from about 1 slm to about 4 slm.

In some embodiments, the RF power is turned on for about 0.1 seconds to about 1 second in each deposition cycle of the PEALD process.

In some embodiments, a temperature for depositing the spacer is in a range from about 25° C. to about 300° C.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIGS. 1-5 illustrate cross-sectional views at various stages of forming a hard mask structure, according to some embodiments of the present disclosure.

FIG. 6 is a circuit diagram of a memory cell of a memory device, according to some embodiments of the present disclosure.

FIGS. 7-12 illustrate cross-sectional views at various stages of forming a semiconductor structure, according to some embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

As used herein, “around”, “about”, “approximately”, or “substantially” may generally mean within 20 percent, or within 10 percent, or within 5 percent of a given value or range. Numerical quantities given herein are approximate meaning that the term “around”, “about”, “approximately”, or “substantially” can be inferred if not expressly stated. One skilled in the art will realize, however, that the values or ranges recited throughout the description are merely examples, and may be reduced or varied with the sown-scaling of the integrated circuits.

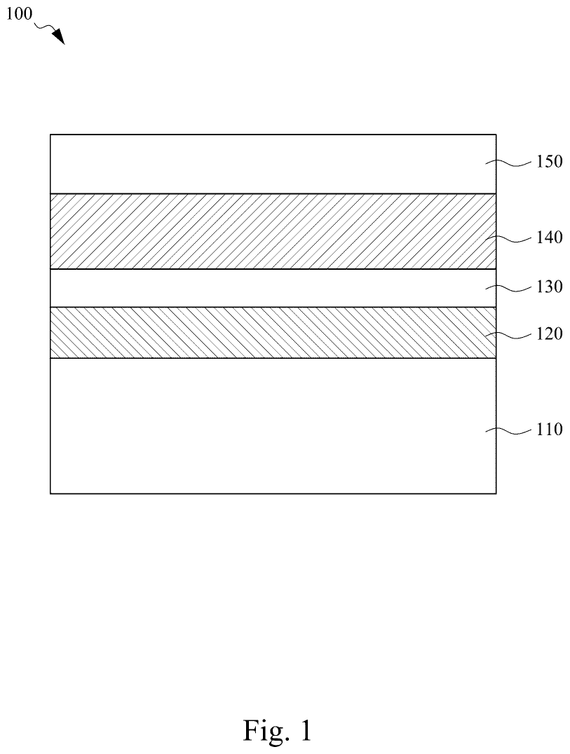

FIGS. 1-6 illustrate cross-sectional views at various stages of forming a hard mask structure, according to some embodiments of the present disclosure. In FIG. 1, a hard mask structure 100 is shown. In some embodiments, the hard mask structure 100 may include a first hard mask 110, a first dielectric layer 120 over the first hard mask 110, a second dielectric layer 130 over the first dielectric layer 120, an underlayer 140 over the second dielectric layer 130, and a second hard mask 150 over the underlayer 140. In some embodiments, the first hard mask 110 may include a carbon-based material, such as amorphous carbon. In some embodiments, the first dielectric layer 120 may include suitable dielectric material, such as silicon oxynitride (SiON). In some embodiments, the second dielectric layer 130 may include suitable dielectric material, such as silicon oxide (SiO). In some embodiments, the underlayer 140 may include a carbon-based material, such as amorphous carbon. In some embodiments, the second hard mask 150 may include silicon oxide (SiO). In some embodiments, the first hard mask 110 and the underlayer 140 are made of a same material, such as amorphous carbon. On the other hand, the second dielectric layer 130 and the second hard mask 150 are made of a same material, such as silicon oxide.

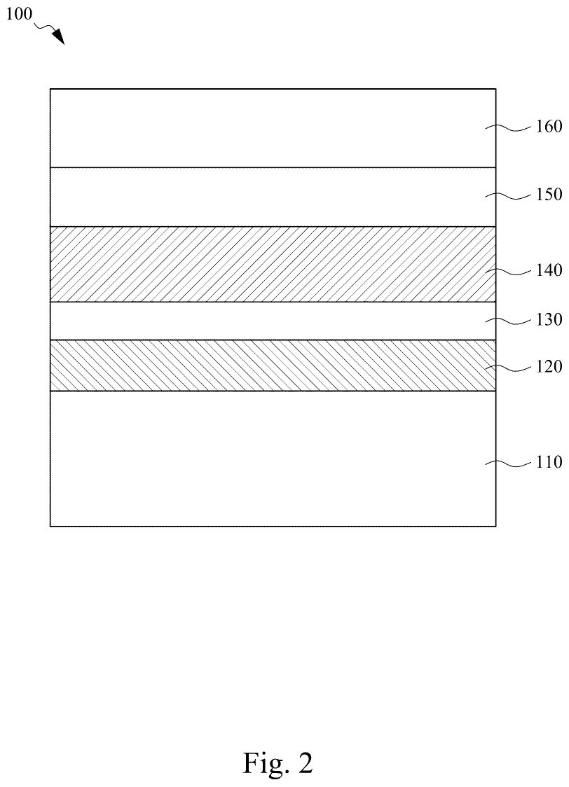

Referring to FIG. 2, a photoresist layer 160 may be formed over the second hard mask 150. The photoresist layer 160 may be formed by coating, e.g., a spin-coating process. Photoresist material is a light-sensitive compound extensively employed in semiconductor fabrication. Generally, the photoresist material is made of organic polymers and/or photosensitive compounds, and can be classified into two types: positive photoresists and negative photoresists, with each type responding differently to exposure to light. Positive photoresists become soluble when exposed to a source of light, such as ultraviolet light. Negative photoresists, on the other hand, become less soluble upon exposure to light. In some embodiments, the photoresist layer 160 may include a positive photoresist material.

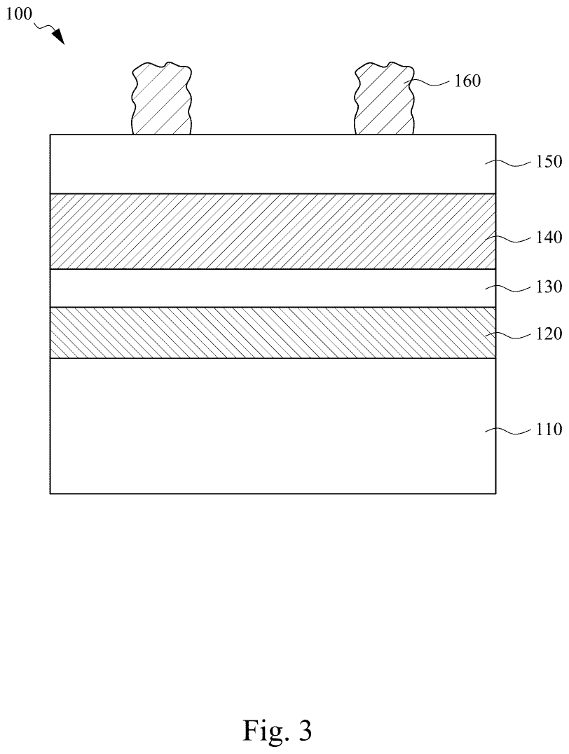

Referring to FIG. 3, a patterning process is performed to pattern the photoresist layer 160 according to a predetermined pattern. Due to the unsatisfying patterning process performance, the patterned photoresist layer 160 may include a rough surface.

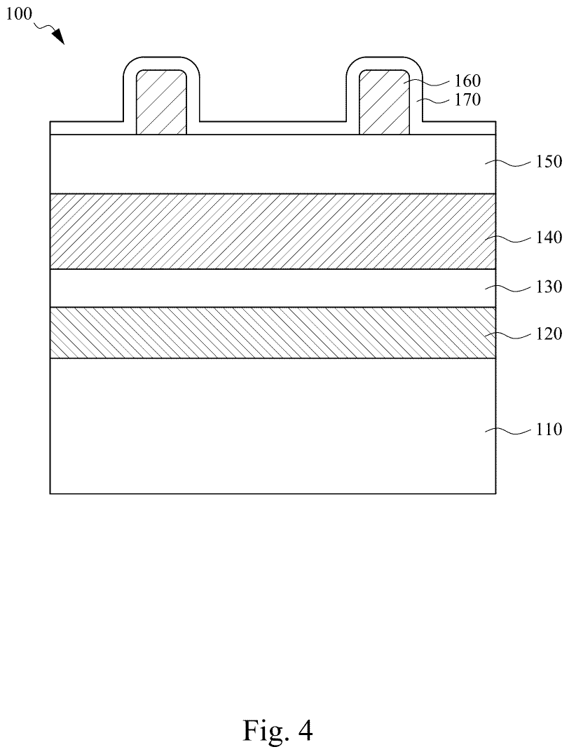

Referring to FIG. 4, a spacer 170 is deposited conformally over the patterned photoresist layer 160. In some embodiments, the spacer 170 may be formed by an ALD process (such as plasma enhanced ALD; PEALD) at a low temperature between about 25° C. to about 300° C., and at a pressure up to about 10 Torr. ALD is a technique that uses sequential self-limiting reactions to deposit thin layers of materials. The ALD process uses surface-mediated deposition reactions to cyclically deposit films layer by layer. As an example the ALD cycle may include the following operations: (i) the first (inorganic) precursor (e.g., silicon) is supplied to the chamber and it reacts with the surface species, (ii) the excess precursor and possible byproducts are removed from the chamber by purging with inert gas such as nitrogen (N), helium (He), or argon (Ar), (iii) optionally igniting the plasma, and (iv) purge byproducts from the chamber. In an ideal case a monolayer of a hybrid inorganic-organic material is formed. To deposit thicker films this basic ALD cycle is repeated as many times as needed to reach the targeted film thickness. In some embodiments, the spacer 170 is deposited to a thickness between about 2 nm and about 30 nm. In some embodiments, the spacer 170 is made of oxide, such as silicon oxide (SiO).

In the present disclosure, the spacer 170 is silicon oxide, and may be deposited using a PEALD process. The PEALD process may include several deposition cycles. In a deposition cycle, oxygen source and silicon source may be supplied into a deposition chamber with carrier gas. In some embodiments, the oxygen source may include oxygen (O₂), ozone (O₃), water (H₂O), or other suitable oxygen source. The silicon source may include silane, dichlorosilane, or the like. The carrier gas may include argon (Ar), nitrogen (N₂), or other suitable carrier gas.

In a first step of the deposition cycle, an oxygen source is supplied into the deposition chamber with carrier gas. In a second step of the deposition process, a silicon source is supplied into the deposition chamber with carrier gas. In a third step of the deposition process, a purging process is performed. In a fourth step of the deposition process, an RF power is turned on to ignite the plasma, the oxygen source and the silicon source may react to form a silicon oxide monolayer along the exposed surface of the patterned photoresist layer 160. In a fifth step of the deposition process, a purging process is performed. Then, the deposition cycle is repeated several times to obtain a desired thickness of the spacer 170.

Plasma energy is provided to activate the oxygen source into oxygen plasma. For example, the oxygen plasma may include oxygen radicals (O*) and other activated species that react with the silicon source. Here, the term the “radical” may be referred to as atom or molecule that has neutral charge. In contrast, “ion” may be referred to as atom or molecule that has a net charge.

In some embodiments, PEALD process is performed with a high RF power. In such situation, the RF power will generate high power oxygen radicals. The high power oxygen radicals may etch the patterned photoresist layer 160, and thus the rough surface of the patterned photoresist layer 160 (see FIG. 3) can be repaired during the PEALD process. On the other hand, the oxygen radicals may also react with the silicon source to form the spacer 170. As a result, during the formation of the spacer 170, the surface of the photoresist layer 160 can be repaired, and the spacer 170 can be deposited over the photoresist layer 160 with better coverage and better uniformity. That is, the formation of the spacer 170 and the repair of the photoresist layer 160 may happen at the same time. As a result, once the spacer 170 is formed, the surface of the photoresist layer 160 becomes smoother.

As mentioned above, the PEALD process is performed with a high RF power. For example, the RF power is in a range from about 200 W to about 1000 W. If the RF power is too low (e.g., much lower than 200 W), the oxygen radicals may not be able to repair the surface of the photoresist layer 160. If the RF power is too high (e.g., much higher than 1000 W), the oxygen radicals may unwantedly consume the photoresist layer 160, and will deteriorate the lithography performance.

In some embodiments, the high power RF power will also generate plasma of the carrier gas (e.g., Ar plasma when the carrier gas is Ar). However, based on the experiment result, it is observed that when the Ar plasma is too strong, the photoresist layer 160 may be etched at a higher speed at the top portion of the photoresist layer 160, resulting in a tapered profile of the photoresist layer 160, which is undesired for a lithography process. Accordingly, the PEALD process is performed using carrier gas with lower flow rate to address the above issue. In some embodiments, the flow rate of the carrier gas (e.g., Ar) is in a range from about 1 slm to about 4 slm.

In some embodiments, the RF power is turned on (in each deposition cycle) for a period of time between about 0.1 seconds and about 1 second. If the period is too long (e.g., much longer than 1 second), the plasma may be too strong, and may unwantedly consume the photoresist layer 160. If the period is too short (e.g., much shorter than 0.1 second), the plasma may not be able to repair the photoresist layer 160.

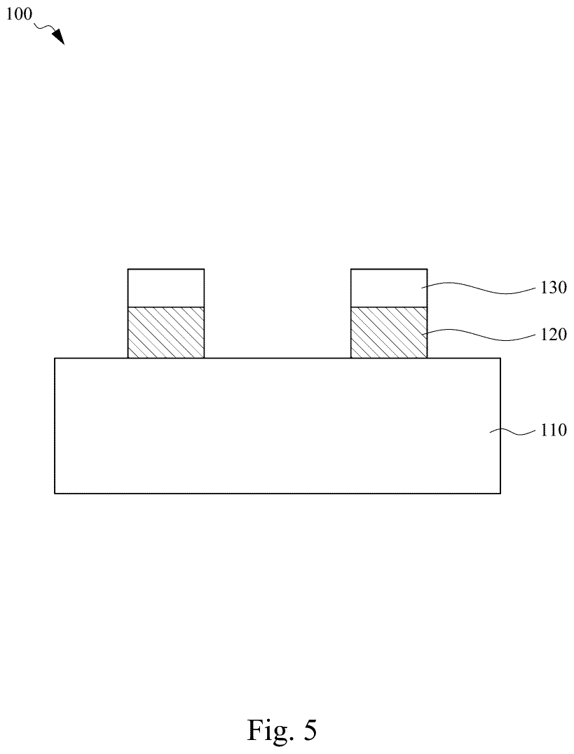

After the PEALD process, as shown in FIG. 5, an etching process is performed to transfer the pattern of the spacer 170 and the photoresist layer 160 to the second dielectric layer 130 and the first dielectric layer 120. In some embodiments, the etching process is an anisotropic etching process, such as reactive ion etch (RIE), neutral beam etch (NBE), other suitable process, or combinations thereof. In the etching process, a CₓF_{y} gas may be used as an etching gas. The CₓF_{y} gas may include C₄F₆ and C₄F₈. Also, Ar gas added to the etching gas is used as a carrier gas. In the etching process, the flow rates of C₄F₆ and C₄F₈ are substantially the same, such as in a range from about 5 sccm to about 200 sccm, respectively. In this case, a dry etching process using plasma may be performed for about 5 seconds to about 200 seconds. After the etching process is complete, the spacer 170, the photoresist layer 160, the second hard mask 150 and the underlayer 140 may be completely removed, and a residue of the second dielectric layer 130 and the first dielectric layer 120 may remain on the first hard mask 110. In some embodiments, the spacer 170, the photoresist layer 160, the second hard mask 150, the underlayer 140, the second dielectric layer 130, and the first dielectric layer 120 are etched in a single etching process using the same etchant including C₄F₆ and C₄F₈, and the etching process may be stopped until the first hard mask 110 is exposed.

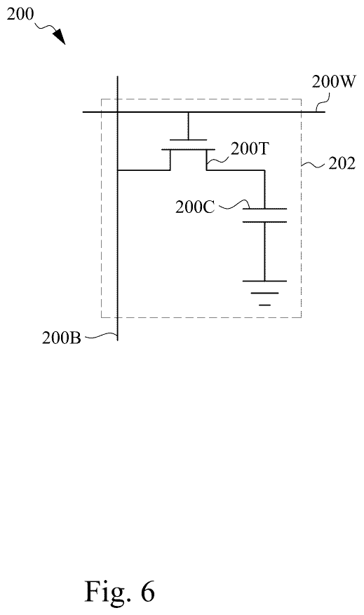

FIG. 6 is a circuit diagram of a memory cell of a memory device, according to some embodiments of the present disclosure. With reference to FIG. 6, a memory device 200 consists of multiple memory cells 202 arranged in a rectangular matrix configuration. In some embodiments, the memory device 200 is a dynamic random access memory (DRAM) device. The memory cell 202 of the memory device 200 consists of a transistor 200T and a capacitor 200C electrically connected to the transistor 200T as main structures. The one side of capacitor 200C is coupled with the drain region of the transistor 200T and the other side of the capacitor 200C is coupled to the ground. The memory device 200 further includes a word line 200W coupled with the gate region of the transistor 200T, and a bit line 200B coupled with the source of the transistor 200T.

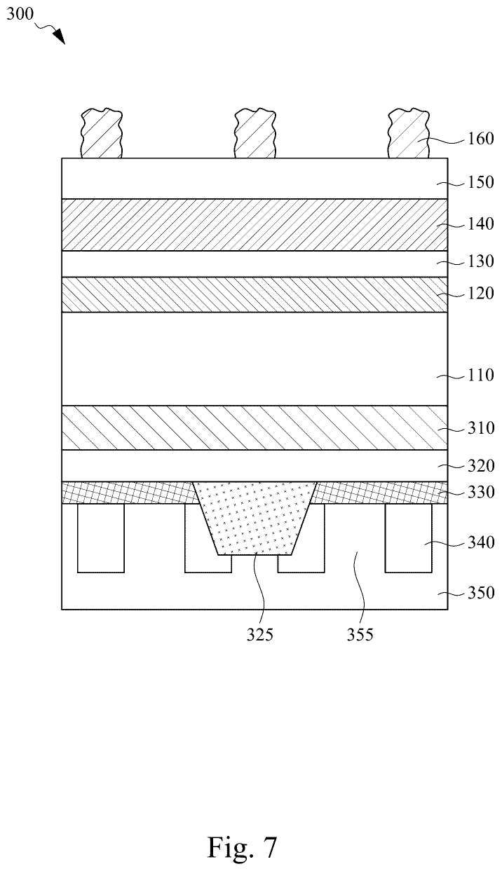

FIGS. 7-12 illustrate cross-sectional views at various stages of forming a semiconductor structure, according to some embodiments of the present disclosure. Referring to FIG. 7, a substrate 350 may be provided. The substrate 350 may be formed of, for example, silicon, doped silicon, silicon germanium, silicon on insulator, silicon on sapphire, silicon germanium on insulator, silicon carbide, germanium, gallium arsenide, gallium phosphide, gallium arsenide phosphide, indium phosphide, indium gallium phosphide, or any other IV-IV, III-V or I-VI semiconductor material.

Still referring to FIG. 7, an isolation layer 340 may be formed in the substrate 350, and a plurality of active regions of the substrate 350 may be defined by the isolation layer 340. A patterning process may be performed to pattern the substrate 350 to define positions of the plurality of active regions. An etching process may be performed after the patterning process to form a plurality of trenches in the substrate 350. After the etching process, an insulating material such as silicon oxide, silicon nitride, silicon oxynitride, silicon nitride oxide, or fluoride-doped silicate, may be used to fill the plurality of trenches by a deposition process. A planarization process, such as chemical mechanical polishing, may be performed after the deposition process to remove excess material and proved a substantially flat surface for subsequent processing steps and conformally form the isolation layer 340 and the plurality of active regions.

A plurality of doped regions 355 may be formed in the active regions. The doped regions 355 may be formed by an implantation process using dopant such as phosphorus, arsenic, or antimony. The doped regions 355 may serve as source/drain regions.

A buffer layer 330 may be formed on the substrate 350. The buffer layer 330 may be formed as a stacked layer or a single layer including silicon oxide, silicon nitride, silicon oxynitride, silicon nitride oxide, fluoride-doped silicate, or the like. At least one conductive portion 325 may be formed in the buffer layer 330 and contacting the doped regions 355 and the isolation layer 340 of the substrate 350. A plurality of openings may be formed in the buffer layer 330 and extending into portions of the doped regions 355 and the isolation layer 340 of the substrate 350. A patterning process may be performed to pattern the buffer layer 330 and portions of the isolation layer 340 of the substrate 350 to define the positions of the openings. An etching process may be performed after the patterning process to form the openings in the buffer layer 330 and extending into portions of the doped regions 355 and the isolation layer 340 of the substrate 350.

Next, the plurality of conductive portions 325 may be respectively correspondingly formed in the openings. In some embodiments, a conductive material, for example, doped polysilicon, a metal, or a metal silicide may be deposited into the openings by a metallization process. After the metallization process, a planarization process, such as chemical mechanical polishing, may be performed to remove excess material, proved a substantially flat surface for subsequent processing steps, and conformally form the plurality of the conductive portions 325. The plurality of the conductive portions 325 may be electrically connected to center portions of the some of the doped regions 355. In some embodiments, the conductive portions 325 may serve as bit line contacts.

A conductive layer 320 may be formed on the substrate 350. In some embodiments, the conductive layer may be formed on the buffer layer 330 and the plurality of conductive portions 325. The conductive layer 320 may be formed of, for example, a conductive material such as polycrystalline silicon, polycrystalline silicon germanium, metal nitride, metal silicide, metal oxide, metal, or a combination thereof. In some embodiments, the conductive layer 320 are bit line layers. In some embodiments, the conductive layer 320 is formed on an array region of the substrate 350.

A dielectric layer 310 may be formed on the conductive layer 320. In some embodiments, the dielectric layer 310 covers the conductive layer 320. In some embodiments, the dielectric layer 310 may be or include a spin-on-dielectric (SOD) oxide layer, a silicon nitride layer, or a combination thereof.

Then, a hard mask structure 100 is formed over the dielectric layer 310. The details of the hard mask structure 100 have been described in FIGS. 1-5, and thus similar elements are labeled the same. In some embodiments, the hard mask structure 100 may include a first hard mask 110, a first dielectric layer 120 over the first hard mask 110, a second dielectric layer 130 over the first dielectric layer 120, an underlayer 140 over the second dielectric layer 130, and a second hard mask 150 over the underlayer 140. In some embodiments, the first hard mask 110 may include a carbon-based material, such as amorphous carbon. In some embodiments, the first dielectric layer 120 may include suitable dielectric material, such as silicon oxynitride (SiON). In some embodiments, the second dielectric layer 130 may include suitable dielectric material, such as silicon oxide (SiO). In some embodiments, the underlayer 140 may include a carbon-based material, such as amorphous carbon. In some embodiments, the second hard mask 150 may include silicon oxide (SiO). In some embodiments, the first hard mask 110 and the underlayer 140 are made of a same material, such as amorphous carbon. On the other hand, the second dielectric layer 130 and the second hard mask 150 are made of a same material, such as silicon oxide.

As shown in FIG. 7, a photoresist layer 160 may be formed over the second hard mask 150. The photoresist layer 160 may be formed by coating, e.g., a spin-coating process. In some embodiments, the photoresist layer 160 may include a positive photoresist material. Next, a patterning process is performed to pattern the photoresist layer 160 to according to a predetermined pattern. Due to the unsatisfying patterning process performance, the patterned photoresist layer 160 may include a rough surface. As a result, the patterned photoresist layer 160 may be formed on the second hard mask 150, and thus the hard mask structure 100 illustrated in FIG. 1 is formed on the dielectric layer 310. In some embodiments, the patterned photoresist layer 160 is on an array region of the substrate 350.

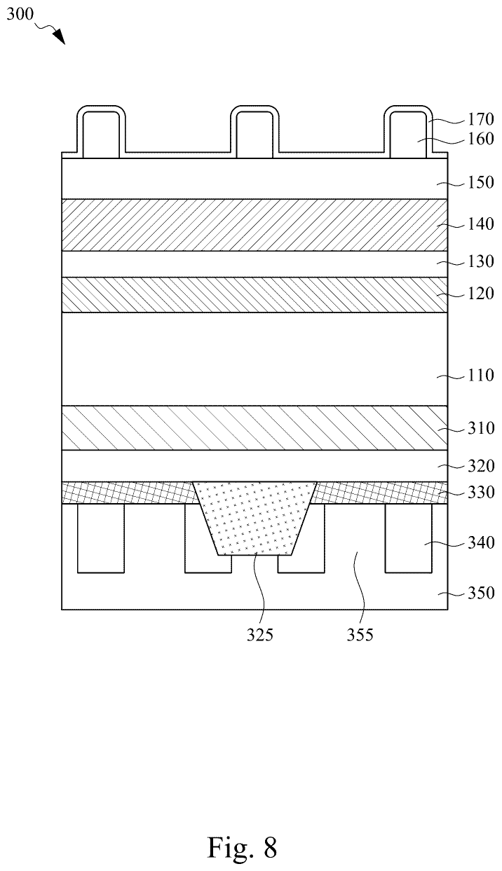

Referring to FIG. 8, a spacer 170 is deposited conformally over the patterned photoresist layer 160. In some embodiments, the spacer 170 may be formed by an ALD process (such as plasma enhanced ALD; PEALD) at a low temperature between about 25° C. to about 300° C., and at a pressure up to about 10 Torr. In some embodiments, the spacer 170 is deposited to a thickness between about 2 nm and about 30 nm. In some embodiments, the spacer 170 is made of oxide, such as silicon oxide (SiO).

In the present disclosure, the spacer 170 is silicon oxide, and may be deposited using a PEALD process. The PEALD process may include several deposition cycles. In a deposition cycle, oxygen source and silicon source may be supplied into a deposition chamber with carrier gas. In some embodiments, the oxygen source may include oxygen (O₂), ozone (O₃), water (H₂O), or other suitable oxygen source. The silicon source may include silane, dichlorosilane, or the like. The carrier gas may include argon (Ar), nitrogen (N₂), or other suitable carrier gas.

In a first step of the deposition cycle, an oxygen source is supplied into the deposition chamber with carrier gas. In a second step of the deposition process, a silicon source is supplied into the deposition chamber with carrier gas. In a third step of the deposition process, a purging process is performed. In a fourth step of the deposition process, an RF power is turned on to ignite the plasma, the oxygen source and the silicon source may react to form a silicon oxide monolayer along the exposed surface of the patterned photoresist layer 160. In a fifth step of the deposition process, a purging process is performed. Then, the deposition cycle is repeated several times to obtain a desired thickness of the spacer 170.

Plasma energy is provided to activate the oxygen source into oxygen plasma. For example, the oxygen plasma may include oxygen radicals (O*) and other activated species that react with the silicon source. Here, the term the “radical” may be referred to as atom or molecule that has neutral charge. In contrast, “ion” may be referred to as atom or molecule that has a net charge.

In some embodiments, PEALD process is performed with a high RF power. In such situation, the RF power will generate high power oxygen radicals. The high power oxygen radicals may etch the patterned photoresist layer 160, and thus the rough surface of the patterned photoresist layer 160 (see FIG. 7) can be repaired during the PEALD process. On the other hand, the oxygen radicals may also react with the silicon source to form the spacer 170. As a result, during the formation of the spacer 170, the surface of the photoresist layer 160 can be repaired, and the spacer 170 can be deposited over the photoresist layer 160 with better coverage and better uniformity. That is, the formation of the spacer 170 and the repair of the photoresist layer 160 may happen at the same time. As a result, once the spacer 170 is formed, the surface of the photoresist layer 160 becomes smoother.

As mentioned above, the PEALD process is performed with a high RF power. For example, the RF power is in a range from about 200 W to about 1000 W. If the RF power is too low (e.g., much lower than 200 W), the oxygen radicals may not be able to repair the surface of the photoresist layer 160. If the RF power is too high (e.g., much higher than 1000 W), the oxygen radicals may unwantedly consume the photoresist layer 160, and will deteriorate the lithography performance.

In some embodiments, the high power RF power will also generate plasma of the carrier gas (e.g., Ar plasma when the carrier gas is Ar). However, based on the experiment result, it is observed that when the Ar plasma is too strong, the photoresist layer 160 may be etched at a higher speed at the top portion of the photoresist layer 160, resulting in a tapered profile of the photoresist layer 160, which is undesired for a lithography process. Accordingly, the PEALD process is performed using carrier gas with lower flow rate to address the above issue. In some embodiments, the flow rate of the carrier gas (e.g., Ar) is in a range from about 1 slm to about 4 slm.

In some embodiments, the RF power is turned on (in each deposition cycle) for a period of time between about 0.1 seconds and about 1 second. If the period is too long (e.g., much longer than 1 second), the plasma may be too strong, and may unwantedly consume the photoresist layer 160. If the period is too short (e.g., much shorter than 0.1 second), the plasma may not be able to repair the photoresist layer 160.

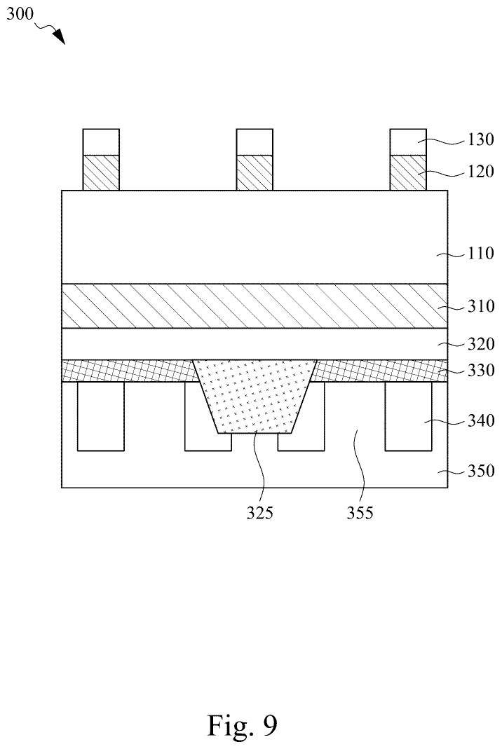

After the PEALD process, as shown in FIG. 9, an etching process is performed to transfer the pattern of the spacer 170 and the photoresist layer 160 to the first dielectric layer 120 and the second dielectric layer 130. In some embodiments, the etching process is an anisotropic etching process, such as reactive ion etch (RIE), neutral beam etch (NBE), other suitable process, or combinations thereof. In the etching process, a CₓF_{y} gas may be used as an etching gas. The CₓF_{y} gas may include C₄F₆ and C₄F₈. Also, Ar gas added to the etching gas is used as a carrier gas. In the etching process, the flow rates of C₄F₆ and C₄F₈ are substantially the same, such as in a range from about 5 sccm to about 200 sccm, respectively. In this case, a dry etching process using plasma may be performed for about 5 seconds to about 200 seconds. After the etching process is complete, the spacer 170, the photoresist layer 160, the second hard mask 150 and the underlayer 140 may be completely removed, and a residue of the second dielectric layer 130 and the first dielectric layer 120 may remain on the first hard mask 110. In some embodiments, the spacer 170, the photoresist layer 160, the second hard mask 150, the underlayer 140, the second dielectric layer 130, and the first dielectric layer 120 are etched in a single etching process using the same etchant including C₄F₆ and C₄F₈, and the etching process may be stopped until the first hard mask 110 is exposed.

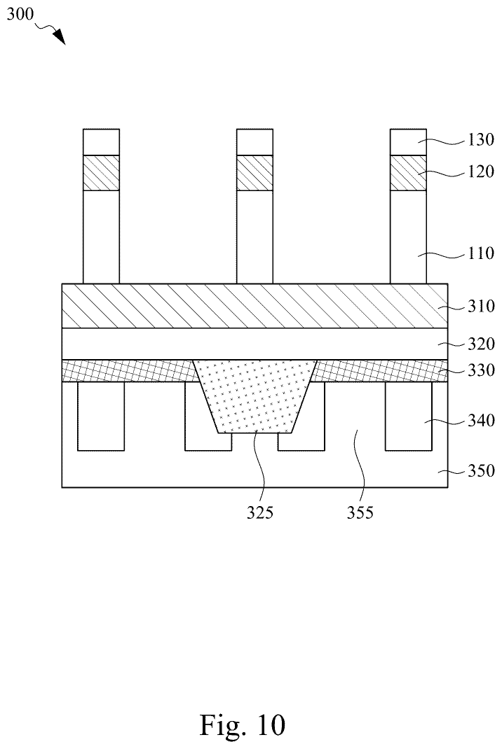

Referring to FIG. 10, the first hard mask 110 is etched by using the second dielectric layer 130 and the first dielectric layer 120 as an etch mask, such that the pattern of the second dielectric layer 130 and the first dielectric layer 120 may be transferred to the first hard mask 110. Specifically, the etching process may be stopped until the dielectric layer 310 is exposed.

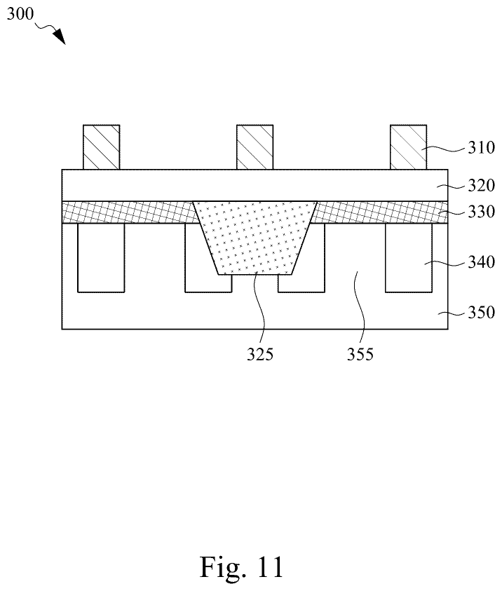

Referring to FIG. 11, after the etching process is complete, the second dielectric layer 130 and the first dielectric layer 120 may be completely removed, the dielectric layer 310 is etched by using the first hard mask 110 as an etch mask, such that the pattern of the first hard mask 110 may be transferred to the dielectric layer 310. In some embodiments, a portion of the conductive layer 320 is exposed from the dielectric layer 310.

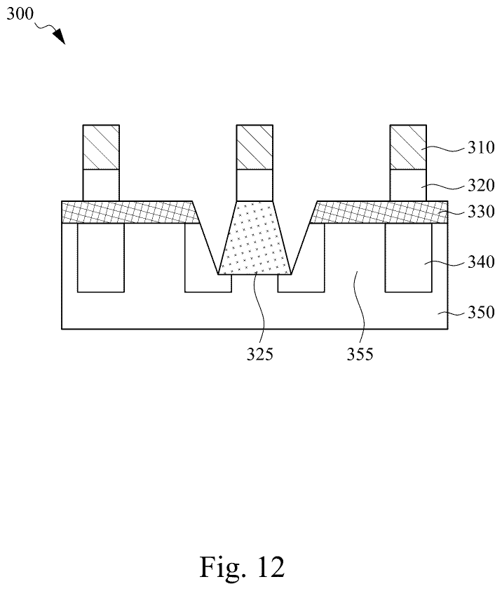

Referring to FIG. 12, the conductive layer 320 is etched by using the dielectric layer 310 as an etch mask, such that the pattern of the dielectric layer 310 may be transferred to the conductive layer 320. In some embodiments, the conductive layer 320 is etched using the dielectric layer 310 as a mask. In some embodiments, a portion of the buffer layer 330 is exposed from the patterned conductive layer 320. In some embodiments, the patterned conductive layer 320 may serve as a bit line.

In some embodiments, the conductive portions 325 are etched by using the dielectric layer 310 as a mask. The conductive portions 325 may have taped shapes. In some embodiments, the conductive portions 325 may serve as bit line contacts. As such, the semiconductor structure 300 is formed. In some embodiments, the semiconductor structure 300 may be an intermediate structure for forming a semiconductor device (e.g., a memory device). In some embodiments, the semiconductor structure 300 may be an example of an intermediate structure for forming a memory device 200 as discussed in FIG. 6.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method for forming a semiconductor structure, comprising:
forming a photoresist layer over a hard mask structure;
patterning the photoresist layer, wherein the patterned photoresist layer has a rough surface;
conformally depositing a spacer over the patterned photoresist layer, wherein during depositing the spacer, the rough surface of the patterned photoresist layer is repaired; and
performing an etching process to the hard mask structure by using the patterned photoresist layer and the spacer as an etch mask.

2. The method of claim 1, wherein the spacer is deposited using a plasma enhanced atomic layer deposition (PEALD) process, and wherein an RF power of the PEALD process is in a range from about 200 W to about 1000 W.

3. The method of claim 2, wherein a flow rate of a carrier gas of the PEALD process is in a range from about 1 slm to about 4 slm.

4. The method of claim 3, wherein the RF power is turned on for about 0.1 seconds to about 1 second in each deposition cycle of the PEALD process.

5. The method of claim 4, wherein a temperature for depositing the spacer is in a range from about 25° C. to about 300° C.

6. The method of claim 2, wherein the spacer is made of silicon oxide and is deposited using the PEALD process, and depositing the spacer comprises supplying a silicon source and an oxygen source, and wherein oxygen radicals are generated from the oxygen source during the PEALD process, and the rough surface of the patterned photoresist layer is repaired through the oxygen radicals.

7. The method of claim 1, wherein the hard mask structure comprises:
a first hard mask;
a first dielectric layer over the first hard mask;
a second dielectric layer over the first dielectric layer;
an underlayer over the second dielectric layer; and
a second hard mask over the underlayer.

8. The method of claim 7, wherein the first hard mask is made of amorphous carbon, the first dielectric layer is made of silicon oxynitride, the second dielectric layer is made of silicon oxide, the underlayer is made of amorphous carbon, and the second hard mask is made of silicon oxide.

9. The method of claim 7, wherein the etching process is performed such that a pattern of the spacer and the patterned photoresist layer is transferred to the first dielectric layer and the second dielectric layer, and wherein the spacer, the patterned photoresist layer, the second hard mask, and the underlayer are completely removed once the etching process is complete.

10. The method of claim 9, wherein etchants of the etching process comprise C₄F₆ and C₄F₈.

11. The method of claim 10, wherein flow rates of the etchants are in a range from about 5 sccm to about 200 sccm, respectively.

12. A method for forming a semiconductor structure, comprising:
forming a photoresist layer over a hard mask structure, wherein the hard mask structure comprises:
a first hard mask;
a first dielectric layer over the first hard mask;
a second dielectric layer over the first dielectric layer;
an underlayer over the second dielectric layer; and
a second hard mask over the underlayer;
patterning the photoresist layer;
conformally depositing a spacer over a patterned photoresist layer; and
performing an etching process to transfer the pattern of the spacer and the patterned photoresist layer to the first dielectric layer and the second dielectric layer, and wherein the spacer, the patterned photoresist layer, the second hard mask, and the underlayer are completely removed once the etching process is complete.

13. The method of claim 12, wherein the first hard mask is made of amorphous carbon, the first dielectric layer is made of silicon oxynitride, the second dielectric layer is made of silicon oxide, the underlayer is made of amorphous carbon, and the second hard mask is made of silicon oxide.

14. The method of claim 12, wherein etchants of the etching process comprise C₄F₆ and C₄F₈.

15. The method of claim 14, wherein flow rates of the etchants are in a range from about 5 sccm to about 200 sccm, respectively.

16. The method of claim 14, wherein the etching process is performed for about 5 seconds to about 200 seconds.

17. The method of claim 12, wherein the spacer is deposited using a plasma enhanced atomic layer deposition (PEALD) process, and wherein an RF power of the PEALD process is in a range from about 200 W to about 1000 W.

18. The method of claim 17, wherein a flow rate of a carrier gas of the PEALD process is in a range from about 1 slm to about 4 slm.

19. The method of claim 18, wherein the RF power is turned on for about 0.1 seconds to about 1 second in each deposition cycle of the PEALD process.

20. The method of claim 19, wherein a temperature for depositing the spacer is in a range from about 25° C. to about 300° C.
